(19) United States
(12) Patent Application Publication
(10) Pub. No.: US 2026/0013083 A1
(43) Pub. Date: Jan. 8, 2026

(54) MOBILE EDGE COMPUTING (MEC) SERVER DEVICE AND METHOD THEREOF

(71) Applicant: JIO PLATFORMS LIMITED, Ahmedabad (IN)

(72) Inventors: Narendra KUMAR, South Delhi (IN); Shakti SINGH, Gurgaon (IN); Amrish BANSAL, Navi Mumbai (IN); Brijesh SHAH, Navi Mumbai (IN); Bajinder Pal SINGH, New Delhi (IN); Sumandas D, Mandya (IN); Madan Kishore GARA, Eluru (IN); Yogesh R K, Bangalore (IN); Shashidhar SIDDAPPGOUDAR, Hyderabad (IN)

(73) Assignee: JIO PLATFORMS LIMITED, Ahmedabad (IN)

(21) Appl. No.: 18/992,311

(22) PCT Filed: Feb. 21, 2024
(86) PCT No.: PCT/IN2024/050190

§ 371 Date: Jan. 8, 2025

(30) Foreign Application Priority Data
Feb. 24, 2023 (IN) 202321012785

(51) Int. Cl. H05K 7/20; G06F 1/20

(52) U.S. Cl. CPC H05K 7/20809; G06F 1/206

(57) ABSTRACT

Disclosed is a Mobile Edge Computing (MEC) server device (100) and use of method thereof. Proposed design of the MEC server device (100) works with a 5G network for edge computing and analysis. The proposed server device (100) has multiple elements integrated on a single board and uses a passive thermal cooling approach. The proposed MEC server device (100) enables equal heat dissipation. Further, the device has a high processing speed and computing functionality.

### RESERVATION OF RIGHTS

A portion of the disclosure of this patent document contains material which is subject to intellectual property rights such as, but are not limited to, copyright, design, trademark, Integrated Circuit (IC) layout design, and/or trade dress protection, belonging to Jio Platforms Limited (JPL) or its affiliates (herein after referred as owner). The owner has no objection to the facsimile reproduction by anyone of the patent document or the patent disclosure, as it appears in the Patent and Trademark Office patent files or records, but otherwise reserves all rights whatsoever. All rights to such intellectual property are fully reserved by the owner.

### TECHNICAL FIELD

The present disclosure relates to a field of computing and wireless communications. More particularly, the present disclosure relates generally to a mobile edge computing (MEC) server and a method for mobile edge computing (MEC).

### BACKGROUND

The following description of related art is intended to provide background information pertaining to the field of the disclosure. This section may include certain aspects of the art that may be related to various features of the present disclosure. However, it should be appreciated that this section be used only to enhance the understanding of the reader with respect to the present disclosure, and not as admissions of prior art.

Conventional edge servers are powerful computing machines placed at network edges where data computation takes place. The edge servers are kept physically close to systems or applications that create data, stored on, or used by, the servers. The edge servers are a next step in the evolution of server technology and are driving advancements in the field of artificial intelligence, machine vision, and deep learning. 5G and edge computing are two inextricably linked technologies as these are both poised to significantly improve performance of applications and enable processing of huge amounts of data in real-time. However, the current available edge servers have various shortcomings.

There is, therefore, a need in the art to provide an improved and advanced edge computing server to meet demand requirements of a network.

### SUMMARY

In an exemplary embodiment, mobile edge computing (MEC) server device is described. The device comprises a scalable processor, a board management controller (BMC), a first ethernet controller, a second ethernet controller, and an application specific integrated circuit (ASIC) integrated on a MEC-board. The scalable processor comprises a platform controller hub (PCH). The MEC server device comprises a high-power control processing unit (CPU), a high-capacity registered dual inline memory module (RDIMMS), a local area network (LAN) on motherboard (LOM), a graphical processor (GP), and a passive thermal cooling arrangement. The passive thermal cooling arrangement includes a plurality of cooling blocks, a plurality of windpipes and a plurality of fins in a top assembly and a bottom assembly.

In some embodiment, heat is distributed in the plurality of fins through the plurality of cooling blocks and the plurality of windpipes.

In some embodiment, distribution of the heat is in equilibrium as heat dissipation aligns and opposite to wind flow.

In some embodiment, the passive thermal cooling arrangement is configured to have amb−50 C, 0.5 m/s air velocity and work in temperature range from 0 to 50 C.

In some embodiment, the first ethernet controller for network interface backhaul packet processing and the second ethernet controller for backhaul packet processing.

In another exemplary embodiment, a method for performing mobile edge computing (MEC) by a MEC server is described. The method comprises performing edge computing of network data associated with a network using a scalable processor. The scalable processor comprises a platform controller hub

(PCH). The method further comprises managing a plurality of functions of a local area network (LAN) on motherboard (LOM). The method further comprises dissipating heat using a passive thermal cooling arrangement. The passive thermal cooling arrangement includes a plurality of cooling blocks, a plurality of fins, and a plurality of windpipes.

In some embodiment, the method comprises managing access to a remote monitoring function using a board management controller (BMC). The BMC is connected to the PCH and a graphical processor unit (GPU).

In some embodiment, the method comprises performing a fronthaul connectivity with a radio unit associated with the network and a backhaul connectivity for optical ethernet associated with the network using a first ethernet controller and a second ethernet controller.

In some embodiment, heat is distributed in the plurality of fins through the plurality of cooling blocks and the plurality of windpipes.

In some embodiment, the passive thermal cooling arrangement is configured to have amb−50 C, 0.5 m/s air velocity and work in temperature range from 0 to 50 C.

In some embodiment, distribution of the heat is in equilibrium as heat dissipation aligns and opposite to wind flow.

In yet another exemplary embodiment, a system for performing mobile edge computing (MEC) is described. The system comprises an integrated system including a scalable processor, a board management controller (BMC), a first ethernet controller, a second ethernet controller, and an application specific integrated circuit (ASIC) integrated on a MEC-board. The scalable processor comprises a platform controller hub (PCH). The system further comprises a high-power control processing unit (CPU), a high-capacity registered dual inline memory module (RDIMMS), a local area network (LAN) on motherboard (LOM), a graphical processor (GP), and a passive thermal cooling arrangement. The passive thermal cooling arrangement includes a plurality of cooling blocks, a plurality of windpipes and a plurality of fins in a top assembly and a bottom assembly.

In some embodiment, heat is distributed in the plurality of fins through the plurality of cooling blocks and the plurality of windpipes.

In some embodiment, the passive thermal cooling arrangement is configured to have amb−50 C, 0.5 m/s air velocity and work in temperature range from 0 to 50 C.

In some embodiment, distribution of the heat is in equilibrium as heat dissipation aligns and opposite to wind flow.

### OBJECTS OF THE PRESENT DISCLOSURE

It is an object of the present disclosure to provide a Mobile Edge Computing (MEC) server device and a method thereof.

It is an object of the present disclosure to provide, on the MEC server device, a Scalable processor, a Platform Controller Hub (PCH), a Baseboard Management Controller (BMC), an Ethernet controller section on a single board.

Furthermore, an additional PCIe may be mounted on the system. Furthermore, a GPU or an accelerator card may be plugged to the MEC server by, mounting them on the PCIe card and may be further cooled by using the passive cooling method.

It is an object of the present disclosure to provide the MEC server device where heat pipes technology and another cooling block is used to spread heat over aluminium fins to maintain CPU temperature. The heat is transferred from RDIMM chips to aluminium heatsinks.

It is an object of the present disclosure to provide the MEC server device having high processing speed and computing functionality.

It is an object of the present disclosure to provide the MEC server device that supports high storage and configuration.

It is an object of the present disclosure to provide the MEC server device having no height deployment restrictions.

Another object of the present disclosure is to provide a mobile edge computing (MEC) server with high computing power and memory closest to the user by adapting an approach of passive thermal cooling.

Another object of the present disclosure is to a mobile edge computing (MEC) server which works in harsh environment such as rain, dust, moisture, shocks and vibrations, and with minimum operating cost.

Another object of the present disclosure adopts a LAN on Mother (LOM) board approach to save over power consumption by the MEC server.

Another object of the present disclosure is to provide a MEC server for providing increased indoor and outdoor performance and enabling a wide range of 5G/6G use cases. This can also significantly enhance user experience in data download rates for all mobile users.

Another object of the present invention is to provide a MEC device with an integrated graphic card support (graphical processor unit).

### BRIEF DESCRIPTION OF THE DRAWINGS

In the figures, similar components and/or features may have the same reference label. Further, various components of the same type may be distinguished by following the reference label with a second label that distinguishes among the similar components. If only the first reference label is used in the specification, the description is applicable to any one of the similar components having the same first reference label irrespective of the second reference label.

The diagrams are for illustration only, which thus is not a limitation of the present disclosure, and wherein:

FIG. 1 illustrates a teardown view of top and bottom side of Mobile Edge Computing (MEC) server device, in accordance with an embodiment of the present disclosure.

FIGS. 2A-F illustrate a top view, a cut out view, a lateral view, a top sectional view, a bottom sectional view, and an isometric view of the MEC server device, in accordance with embodiments of the present disclosure.

FIG. 3 illustrates an exemplary design of an alternate MEC server device, in accordance with an embodiment of the present disclosure.

FIG. 4 illustrates an exemplary flow diagram representation depicting a method for MEC, in accordance with an embodiment of the present disclosure.

FIG. 5 illustrates an exemplary computer system in which or with which embodiments of the present invention can be utilized in accordance with embodiments of the present disclosure.

### DETAILED DESCRIPTION

In the following description, for the purposes of explanation, various specific details are set forth in order to provide a thorough understanding of embodiments of the present disclosure. It will be apparent, however, that embodiments of the present disclosure may be practiced without these specific details. Several features described hereafter can each be used independently of one another or with any combination of other features. An individual feature may not address all of the problems discussed above or might address only some of the problems discussed above. Some of the problems discussed above might not be fully addressed by any of the features described herein.

The ensuing description provides exemplary embodiments only, and is not intended to limit the scope, applicability, or configuration of the disclosure. Rather, the ensuing description of the exemplary embodiments will provide those skilled in the art with an enabling description for implementing an exemplary embodiment. It should be understood that various changes may be made in the function and arrangement of elements without departing from the spirit and scope of the invention as set forth.

Specific details are given in the following description to provide a thorough understanding of the embodiments. However, it will be understood by one of ordinary skill in the art that the embodiments may be practiced without these specific details. For example, circuits, systems, networks, processes, and other components may be shown as components in block diagram form in order not to obscure the embodiments in unnecessary detail. In other instances, well-known circuits, processes, algorithms, structures, and techniques may be shown without unnecessary detail in order to avoid obscuring the embodiments.

Also, it is noted that individual embodiments may be described as a process which is depicted as a flowchart, a flow diagram, a data flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed but could have additional steps not included in a figure. A process may correspond to a method, a function, a procedure, a subroutine, a subprogram, etc. When a process corresponds to a function, its termination can correspond to a return of the function to the calling function or the main function.

The word “exemplary” and/or “demonstrative” is used herein to mean serving as an example, instance, or illustration. For the avoidance of doubt, the subject matter disclosed herein is not limited by such examples. In addition, any aspect or design described herein as “exemplary” and/or “demonstrative” is not necessarily to be construed as preferred or advantageous over other aspects or designs, nor is it meant to preclude equivalent exemplary structures and techniques known to those of ordinary skill in the art. Furthermore, to the extent that the terms “includes,” “has,” “contains,” and other similar words are used in either the detailed description or the claims, such terms are intended to be inclusive-in a manner similar to the term “comprising” as an open transition word-without precluding any additional or other elements.

Reference throughout this specification to “one embodiment” or “an embodiment” or “an instance” or “one instance” means that a particular feature, structure, or characteristic described in connection with the embodiment is included in at least one embodiment of the present invention. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items.

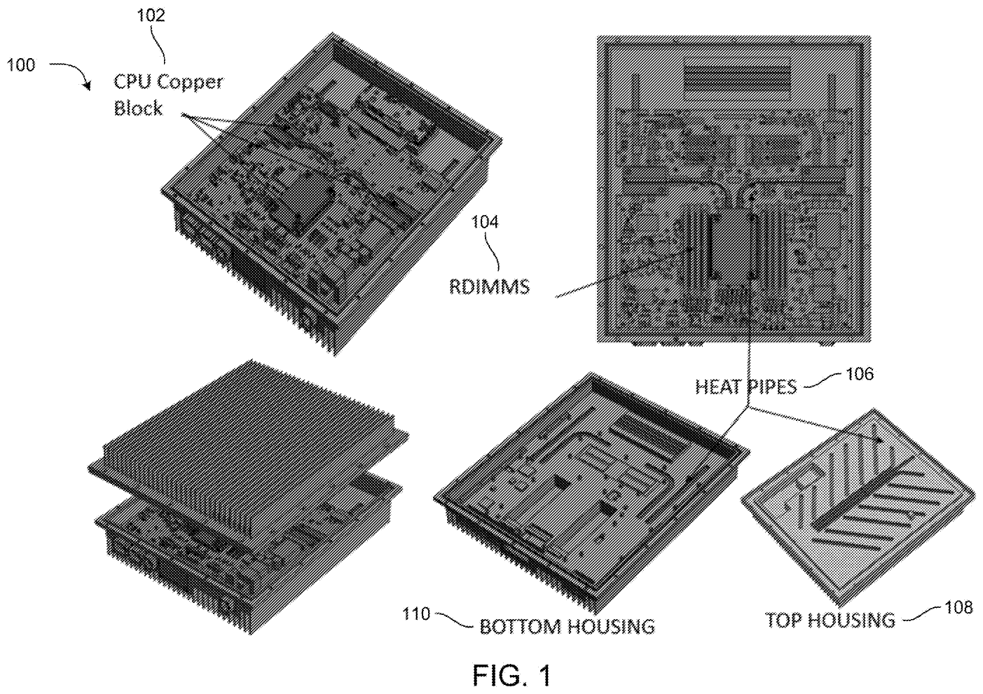

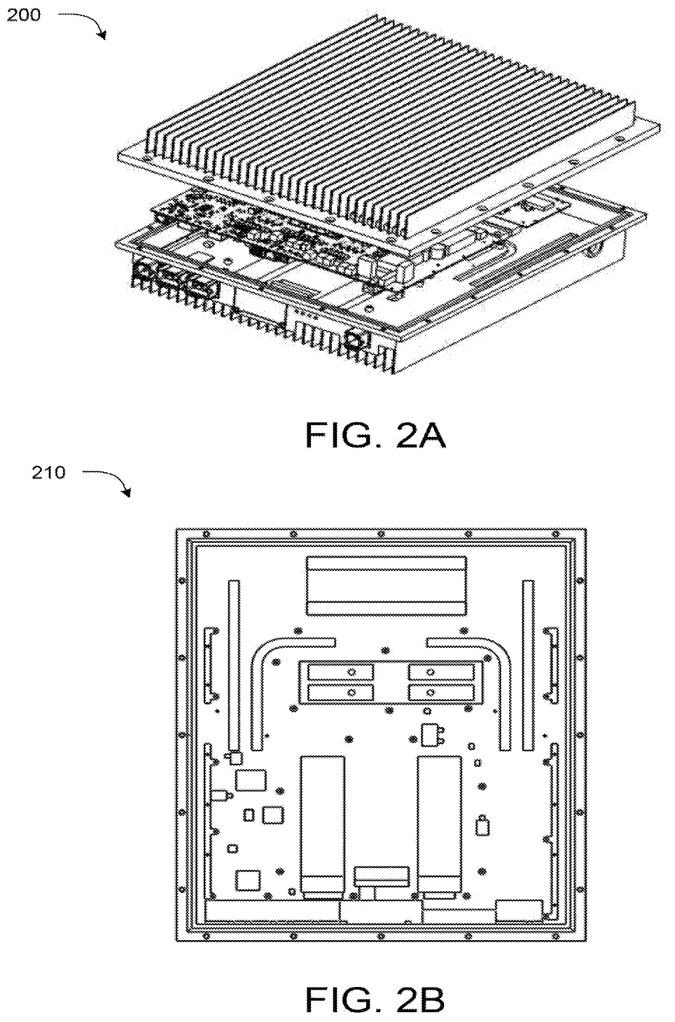

The disclosed indigenously developed Mobile Edge Computing (MEC) server device is designed to work with a 5G core network for edge computing and analysis. Hardware of the MEC device is designed while maintaining lower costs, providing higher reliability, high availability and a passive thermal cooling approach. The device has Baseboard Management Controller (BMC) and Basic Input/Output System (BIOS) firmware. FIG. 1 illustrates a teardown view of top and bottom side of Mobile Edge Computing (MEC) server device 100, in accordance with an embodiment of the present disclosure. The MEC server device has following unique features:
1. Integrated device having Scalable Processor, Platform Controller Hub (PCH), the BMC, Ethernet controller section on a single board. This board may be of multiple layers. Furthermore, an additional PCIe may be mounted on the system. Furthermore, a GPU or an accelerator card may be plugged to the MEC server by, mounting them on the PCIe card and may be further cooled by using the passive cooling method.
2. Passive thermal cooling approach to optimize power consumption and improve system reliability. The passive thermal cooling is achieved with an arrangement of various cooling blocks and heat pipes (106). For example: the disclosed MEC may work on conventional cooling of range (amb−50 C, 0.5 m/s air velocity), with the layout of windpipes and assembly. In this, the heat is distributed in top and bottom side. Hence, half heat is going on bottom fins and half in upper fins. Therefore, the heat transfer mechanism may be enhanced in the present invention. The distribution of heat is in equilibrium, as heat dissipation aligns, opposite to the wind flow.
3. The device is designed with a LAN on Motherboard (LOM) to minimize cost and improve reliability of the device.
4. Thermal design which allows the device to work over wide temperature ranges-from 0 to 50 degree Celsius in a completely outdoor environment and is able to sustain dust, rain, shock and vibrations etc.
5. Integration of graphic card support (graphical processor unit) in the MEC.
6. High processing speed and computing functionality.

Conventional edge servers may be placed close to a user, so that they may develop their application and may access required computational power with minimum delay due to traffic of a backbone network, unlike when using a cloud server/centralized server. The edge server requires high computing power that is achieved through a multicore Central Processing Unit (CPU) and consumes sufficient memory.

However, the disclosed MEC device is provided with a latest generation CPU having higher capacity (e.g., 512 GB or 1 TB) and is based on a provided set of requirements. The MEC device (100) is provided as an overall integrated system having the scalable processor, the PCH, the BMC, and the Ethernet controller (for e.g.: active standby mode 100G/2*100G) section integrated on a single board.

The CPU has 185 W power dissipation capacity which makes CPU temperature unsuitable for passive cooling. The CPU may be of plurality in nature. Further, the CPU has a high-capacity memory that is provided through a Registered Dual In-Line Memory Module (RDIMMS) (104) that is designed for air cooling with only high speed fans. This power dissipation capacity may be further enhanced up to 250 W.

However, the disclosed MEC device (100) utilizes heat pipes technology and other cooling blocks to spread generated heat over aluminium fins 30 to maintain the CPU temperature. The MEC device (100) is designed with a heat transfer mechanism that transfers heat from RDIMM chips (104) to aluminium heatsinks.

The MEC device (100) enables easy and flexible integration of graphic card support (Graphical processor unit).

In an embodiment, the MEC device (100) enhances conventional cooling. The device improves conventional cooling (amb−50 C, 0.5 m/s air velocity) parameters by laying down new layout of windpipes and assembly where generated heat is distributed on top and bottom sides. Half of the heat is transferred on bottom fins and half in upper fins leading to an enhanced heat transfer mechanism. Further, the device enables heat distribution to be done in an equilibrium by aligning heat dissipation for all directions of wind flow, which includes opposite to wind flow. In brief, multiple planned heat dissipation points of the device helps in quick disposal of generated heat. This MEC device may be mounted on a pole or at an altitude.

The MEC device (100) has a high processing speed and efficient computing functionality.

The MEC device (100) provides high storage/configuration support as compared to earlier available versions. In addition, the MEC device (100) has no height deployment restrictions.

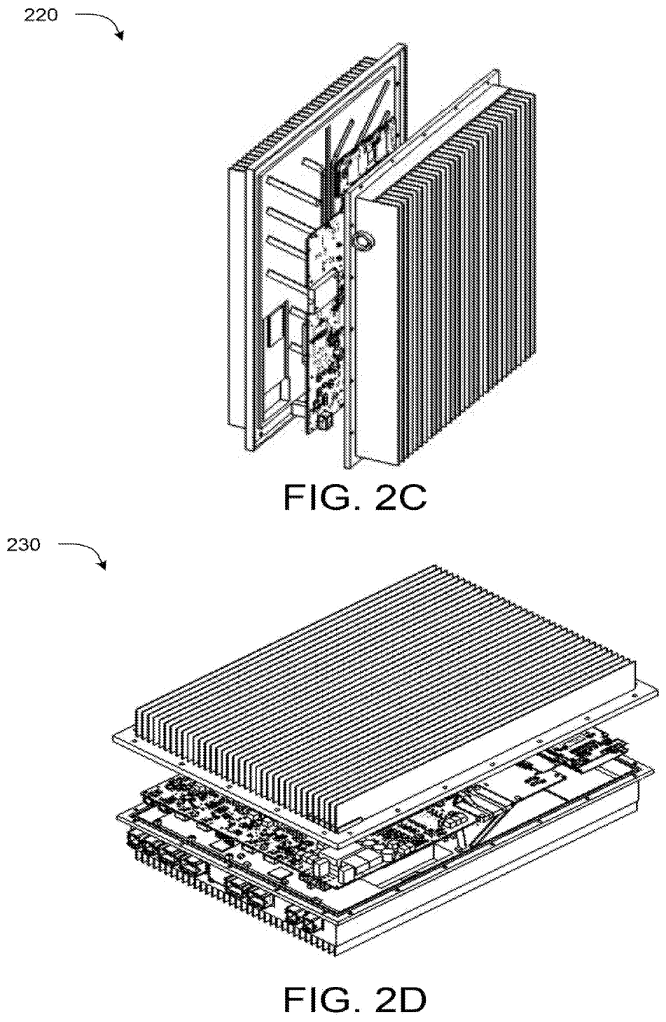

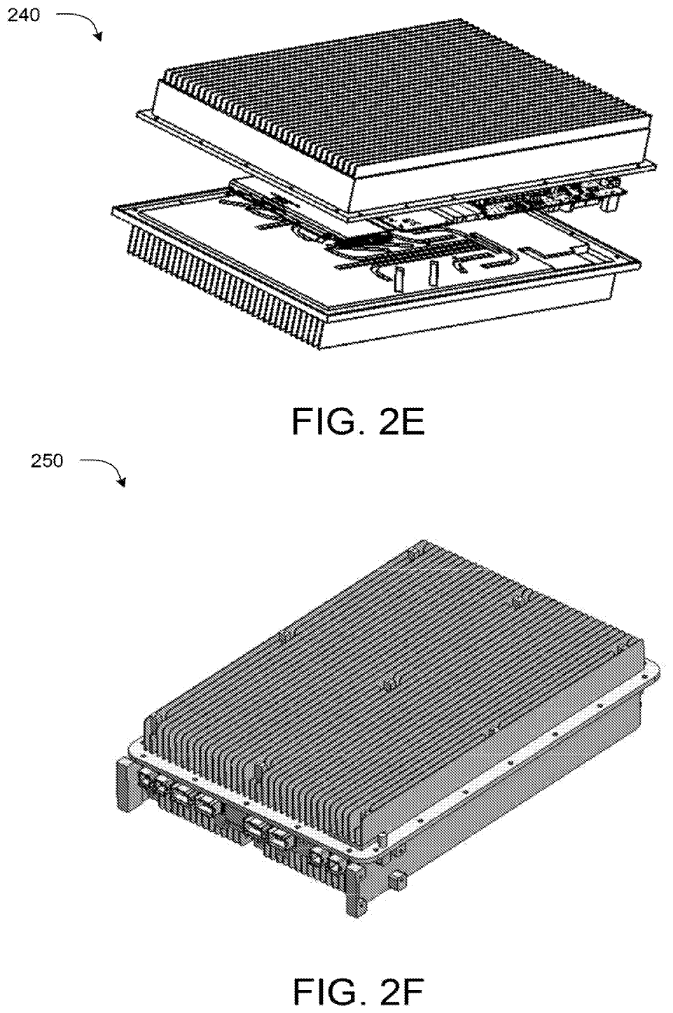

FIGS. 2A-F illustrate a top view 200, a cut out view 210, a lateral view 220, a top sectional view 230, a bottom sectional view 240, and an isometric view 250 of the MEC server device (100), in accordance with embodiments of the present disclosure.

In an embodiment, the MEC server device (100) comprises of:
1. Scalable processor
2. Baseboard management controller
3. Ethernet controllers for processing of network interface backhaul packet processing
4. Ethernet controllers for processing of backhaul packet processing. For e.g.: active standby mode at least of 100G capacity.
5. Integrated Graphics Processing Unit (GPU)
6. PCH (Peripheral Controller Hub)

The scalable processor is provided with an external Peripheral Controller Hub (PCH) to expand Inputs/Outputs and interfaces. A PCH is interfaced on Direct Media Interface (DMI)/Peripheral Component Interconnect Express (PCIe) Genx3 interface with the scalable processor to provide an interface to Serial Peripheral Interface (SPI) flash for Basic Input/Output System (BIOS), PCIe and Serial Advanced Technology Attachment (SATA) for solid-state drive (SSD).

The BMC is used for board management functionality. The BMC provides an Ethernet port for remote monitoring of a unit. The BMC is connected with the PCH through Low Pin count (LPC)/eSPI interface, Universal Serial Bus (USB) and PCIe.

Ethernet Controller-Network connectivity for 100G/4×25G//8×10G/with core 5G backhaul is provided with Ethernet controller which performs backend connectivity functions. The above-mentioned elements are integrated on a single board.

In an embodiment, a high power CPU (for example, 185 W) Thermal Design Power (TDP) is cooled down by using a passive thermal cooling approach. The 512 GB/1 TB capacity RDIMMS are cooled down by using a passive thermal cooling approach. Further, the device uses a LAN on motherboard (LOM) approach to save overall power consumption.

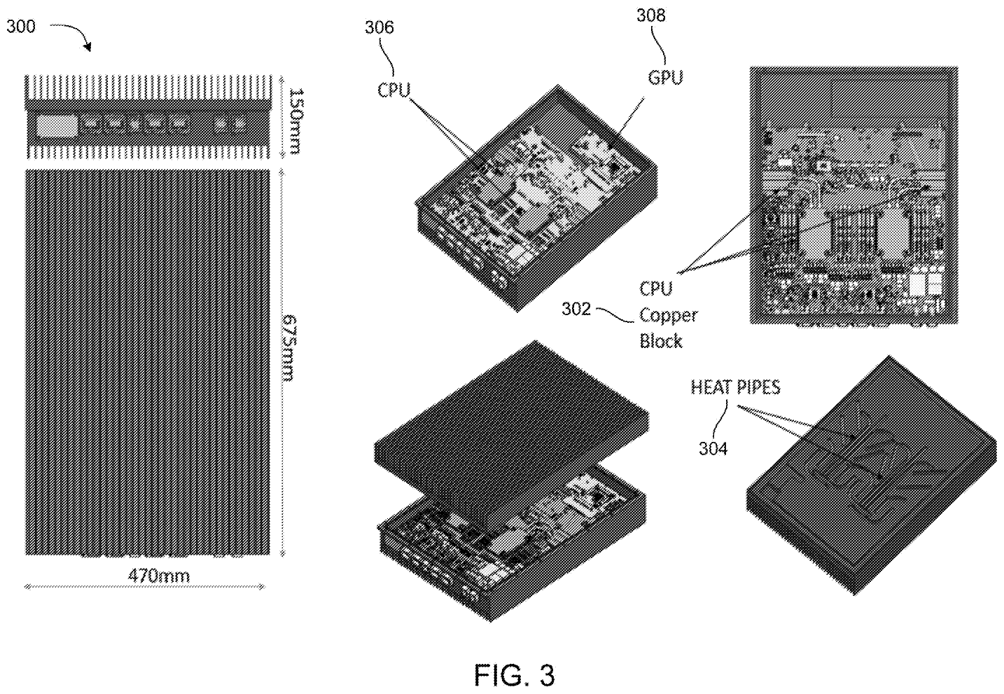

In another embodiment, is disclosed an alternate MEC which has double specifications as compared to the earlier described MEC. FIG. 3 illustrates an exemplary design of the MEC server device 300, in accordance with an embodiment of the present disclosure.

As may be appreciated, the MEC server device (300) may bring server-like computation to the edge servers. The edge servers may be installed in closed enclosures, custom cabinetry in the middle of a desert, a closet, a warehouse, on a desk, or even right in the middle of a welding studio as all of locations are where people encounter problems with data computation. As compared to Commercial off-the-shelf (COT) servers, the MEC server device (300) is designed to work in a harsh environment such as in rain, dust, moisture and vibration. The MEC device has a minimum operating cost, as the service device is completely fan less. In absence of any moving parts present in the device, reliability and availability of the MEC device (300) increases and enables the device to operate at 24×7 over 365 days without any requirement of maintenance.

As may be appreciated, the MEC server device (300) may include a central processing unit (CPU) (306), a graphical processor unit (308), CPU copper block (302) and heat pipes (304).

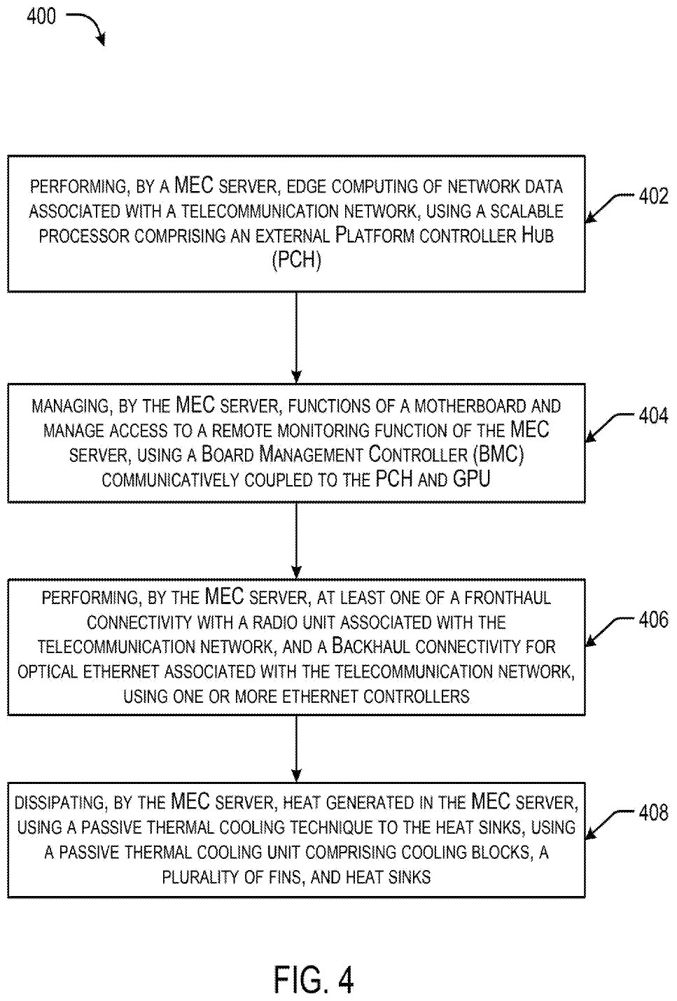

FIG. 4 illustrates an exemplary flow diagram representation 400 depicting a method for Mobile Edge Computing (MEC), in accordance with an embodiment of the present disclosure. As illustrated, at block (402), the method (400) includes performing, by a MEC server (100), edge computing of network data associated with a telecommunication network, using a scalable processor comprising an external Platform controller Hub (PCH).

At block (404), the method (400) includes managing, by the MEC server (100), functions of a motherboard and manage access to a remote monitoring function of the MEC server (100), using a Board Management Controller (BMC) (104) communicatively coupled to the PCH and GPU.

At block (406), the method (400) includes performing, by the MEC server (100), at least one of a fronthaul connectivity with a radio unit associated with the telecommunication network, and a Backhaul connectivity for optical Ethernet associated with the telecommunication network, using one or more Ethernet controllers.

At block (408), the method (400) includes dissipating, by the MEC server (100), heat generated in the MEC server (100), using a passive thermal cooling technique to the heat sinks, using a passive thermal cooling unit comprising cooling blocks, a plurality of fins, and heat sinks.

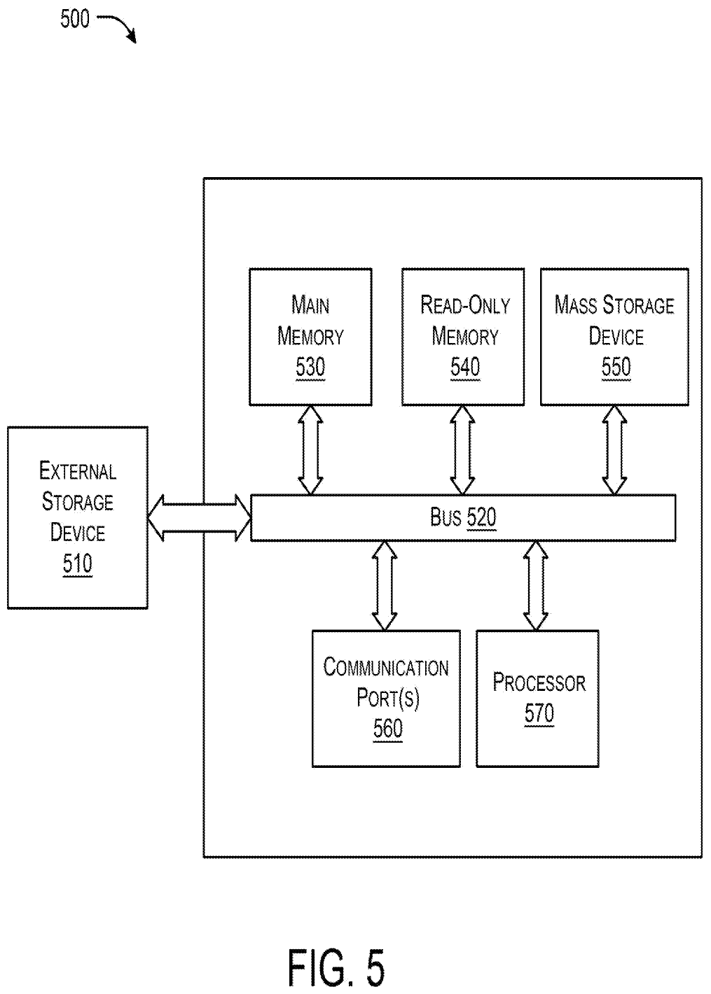

FIG. 5 illustrates an exemplary computer system 500 in which or with which embodiments of the present invention can be utilized in accordance with embodiments of the present disclosure. As shown in FIG. 5, computer system 500 can include an external storage device 510, a bus 520, a main memory 530, a read-only memory 540, a mass storage device 570, a communication port 560, and a processor 570. A person skilled in the art will appreciate that the computer system may include more than one processor and communication ports. Processor 570 may include various modules associated with embodiments of the present invention. Communication port 560 can be any of an RS-232 port for use with a modem-based dialup connection, a 10/100 Ethernet port, a Gigabit or 10 Gigabit port using copper or fiber, a serial port, a parallel port, or other existing or future ports. Communication port 560 may be chosen depending on a network, such as a Local Area Network (LAN), Wide Area Network (WAN), or any network to which computer system connects. Memory 530 can be Random Access Memory (RAM), or any other dynamic storage device commonly known in the art. Read-only memory 540 can be any static storage device(s) e.g., but not limited to, a Programmable Read Only Memory (PROM) chips for storing static information e.g., start-up or BIOS instructions for processor 570. Mass storage 570 may be any current or future mass storage solution, which can be used to store information and/or instructions. Exemplary mass storage solutions include, but are not limited to, Parallel Advanced Technology Attachment (PATA) or Serial Advanced Technology Attachment (SATA) hard disk drives or solid-state drives (internal or external, e.g., having Universal Serial Bus (USB) and/or Firewire interfaces), one or more optical discs, Redundant Array of Independent Disks (RAID) storage, e.g. an array of disks (e.g., SATA arrays).

Bus 520 communicatively may couple processor(s) 570 with the other memory, storage, and communication blocks. Bus 520 can be, e.g., a Peripheral Component Interconnect (PCI)/PCI Extended (PCI-X) bus, Small Computer System Interface (SCSI), USB, or the like, for connecting expansion cards, drives, and other subsystems as well as other buses, such a front side bus (FSB), which connects processor 570 to a software system.

Optionally, operator and administrative interfaces, e.g., a display, keyboard, joystick, and a cursor control device, may also be coupled to bus 520 to support direct operator interaction with a computer system. Other operator and administrative interfaces can be provided through network connections connected through communication port 560. The external storage device 510 can be any kind of external hard-drives, floppy drives, IOMEGA® Zip Drives, Compact Disc-Read Only Memory (CD-ROM), Compact Disc-Re-Writable (CD-RW), Digital Video Disk-Read Only Memory (DVD-ROM). Components described above are meant only to exemplify various possibilities. In no way should the aforementioned exemplary computer system limit the scope of the present disclosure.

While the foregoing describes various embodiments of the invention, other and further embodiments of the invention may be devised without departing from the basic scope thereof. The scope of the invention is determined by the claims that follow. The invention is not limited to the described embodiments, versions or examples, which are included to enable a person having ordinary skill in the art to make and use the invention when combined with information and knowledge available to the person having ordinary skill in the art.

### Advantages of the Present Disclosure

The present disclosure supports to provide a MEC server device and a method thereof.

The present disclosure provides the MEC server device that has a high processing speed and computing functionality.

The present disclosure provides the MEC server device that supports high storage and configuration.

The present disclosure provides the MEC server device having no height deployment restrictions.

The present disclosure provides the MEC server device where heat pipes technology and another cooling block is used to spread heat over aluminium fins to maintain CPU temperature. The heat is transferred from RDIMM chips to aluminium heatsinks.

The present disclosure enables easy deployment of the MEC server device on telecom power, street poles or walls inside buildings.

The present disclosure provides zero maintenance cost for the MEC server device.

The present disclosure provides the MEC server device that is highly reliable and is readily available.

We claim:

1. A mobile edge computing (MEC) server device (100), the device comprising:
a scalable processor, a board management controller (BMC), a first ethernet controller, a second ethernet controller, and an application specific integrated circuit (ASIC) integrated on a MEC-board, wherein the scalable processor comprises a platform controller hub (PCH);
a high-power control processing unit (CPU) (306);
a high-capacity registered dual inline memory module (RDIMMS) (104);
a local area network (LAN) on motherboard (LOM);
a graphical processor unit (GPU) (308); and
a passive thermal cooling arrangement including a plurality of cooling blocks (102, 302), a plurality of windpipes (106, 304) and a plurality of fins in a top assembly and a bottom assembly.

2. The MEC server device claimed as in claim 1, wherein heat is distributed in the plurality of fins through the plurality of cooling blocks (102, 302) and the plurality of windpipes (106, 304).

3. The MEC server device claimed as in claim 1, wherein distribution of the heat is in equilibrium as heat dissipation aligns and opposite to wind flow.

4. The MEC server device claimed as in claim 1, wherein the passive thermal cooling arrangement is configured to have amb−50 C, 0.5 m/s air velocity and work in temperature range from 0 to 50 C.

5. The MEC server device claimed as in claim 1, wherein the first ethernet controller for network interface backhaul packet processing and the second ethernet controller for backhaul packet processing.

6. A method for performing mobile edge computing (MEC) by a MEC server (100), the method comprising:
performing edge computing of network data associated with a network using a scalable processor, wherein the scalable processor comprises a platform controller hub (PCH);
managing a plurality of functions of a local area network (LAN) on motherboard (LOM); and
dissipating heat using a passive thermal cooling arrangement, wherein the passive thermal cooling arrangement includes a plurality of cooling blocks (102), a plurality of fins, and a plurality of windpipes (106).

7. The method claimed as in claim 6 further comprising: managing access to a remote monitoring function using a board management controller (BMC), wherein the BMC is connected to the PCH and a graphical processor unit (GPU) (308).

8. The method claimed as in claim 6 further comprising: performing a fronthaul connectivity with a radio unit associated with the network and a backhaul connectivity for optical ethernet associated with the network using a first ethernet controller and a second ethernet controller.

9. The method claimed as in claim 6, wherein heat is distributed in the plurality of fins through the plurality of cooling blocks (102, 302) and the plurality of windpipes (106, 304).

10. The method claimed as in claim 6, wherein the passive thermal cooling arrangement is configured to have amb−50 C, 0.5 m/s air velocity and work in temperature range from 0 to 50 C.

11. The method claimed as in claim 6, wherein distribution of the heat is in equilibrium as heat dissipation aligns and opposite to wind flow.

12. A system for performing mobile edge computing (MEC) comprising:
an integrated system including a scalable processor, a board management controller (BMC), a first ethernet controller, a second ethernet controller, and an application specific integrated circuit (ASIC) integrated on a MEC-board, wherein the scalable processor comprises a platform controller hub (PCH);
a high-power control processing unit (CPU) (306);
a high-capacity registered dual inline memory module (RDIMMS) (104);
a local area network (LAN) on motherboard (LOM);
a graphical processor unit (GPU) (308); and
a passive thermal cooling arrangement including a plurality of cooling blocks (102, 302), a plurality of windpipes (106, 304) and a plurality of fins in a top assembly and a bottom assembly.

13. The system claimed as in claim 10, wherein heat is distributed in the plurality of fins through the plurality of cooling blocks (102, 302) and the plurality of windpipes (106, 304).

14. The system claimed as in claim 10, wherein the passive thermal cooling arrangement is configured to have amb−50 C, 0.5 m/s air velocity and work in temperature range from 0 to 50 C.

15. The system claimed as in claim 10, wherein distribution of the heat is in equilibrium as heat dissipation aligns and opposite to wind flow.

16. A computer program product comprising a non-transitory computer-readable medium comprising instructions that, when executed by one or more processors, cause the one or more processors to execute a method for performing mobile edge computing (MEC) by a MEC server (100), the method comprising:
performing edge computing of network data associated with a network using a scalable processor, wherein the scalable processor comprises a platform controller hub (PCH);
managing a plurality of functions of a local area network (LAN) on motherboard (LOM); and
dissipating heat using a passive thermal cooling arrangement, wherein the passive thermal cooling arrangement includes a plurality of cooling blocks (102), a plurality of fins, and a plurality of windpipes (106).

17. A computer program product comprising a non-transitory computer-readable medium comprising instructions that, when executed by one or more processors, cause the one or more processors to execute a system for performing mobile edge computing (MEC) comprising:
an integrated system including a scalable processor, a board management controller (BMC), a first ethernet controller, a second ethernet controller, and an application specific integrated circuit (ASIC) integrated on a MEC-board, wherein the scalable processor comprises a platform controller hub (PCH);
a high-power control processing unit (CPU) (306);
a high-capacity registered dual inline memory module (RDIMMS) (104);
a local area network (LAN) on motherboard (LOM);
a graphical processor unit (GPU) (308); and
a passive thermal cooling arrangement including a plurality of cooling blocks (102, 302), a plurality of windpipes (106, 304) and a plurality of fins in a top assembly and a bottom assembly.
